(19) United States
(12) Patent Application Publication
(10) Pub. No.: US 2025/0287567 A1
(43) Pub. Date: Sep. 11, 2025

(54) SEMICONDUCTOR DEVICE HAVING INFORMATION STORAGE STRUCTURE

(71) Applicant: Samsung Electronics Co., Ltd., Suwon-si (KR)

(72) Inventors: Dongkwan Baek, Suwon-si (KR); Jaewan Chang, Suwon-si (KR); Chunhum Cho, Suwon-si (KR); Hyunbin Kim, Suwon-si (KR); Junseok Lee, Suwon-si (KR)

(21) Appl. No.: 18/965,127

(22) Filed: Dec. 2, 2024

(30) Foreign Application Priority Data
Mar. 5, 2024 (KR) 10-2024-0031201

(51) Int. Cl. H10B 12/00

(52) U.S. Cl. CPC H10B 12/315; H10B 12/033

(57) ABSTRACT

A semiconductor device includes a lower structure having a conductive region, and an information storage structure on the lower structure. The information storage structure includes a lower electrode electrically connected to the conductive region, a support layer on a side surface of the lower electrode, a dielectric layer on the lower electrode and the support layer, an interface layer between the lower electrode and the dielectric layer, passivation layers between the support layer and the dielectric layer, and an upper electrode on the dielectric layer.

### CROSS-REFERENCE TO RELATED APPLICATION(S)

This application claims benefit of priority under 35 U.S.C. § 119 to Korean Patent Application No. 10-2024-0031201 filed on Mar. 5, 2024 in the Korean Intellectual Property Office, the disclosure of which is incorporated herein by reference in its entirety.

### BACKGROUND

The present inventive concept relates to a semiconductor device having an information storage structure.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine isolation distance.

### SUMMARY

An aspect of the present inventive concept provides a semiconductor device including an information storage structure.

According to an aspect of the present inventive concept, there is provided a semiconductor device including a lower structure having a conductive region, and an information storage structure on the lower structure. The information storage structure may include a lower electrode electrically connected to the conductive region, a support layer on a side surface of the lower electrode, a dielectric layer covering the lower electrode and the support layer, an interface layer between the lower electrode and the dielectric layer, passivation layers between the support layer and the dielectric layer, and an upper electrode on the dielectric layer.

According to another aspect of the present inventive concept, there is provided a semiconductor device including a lower structure having conductive regions, and an information storage structure on the lower structure. The information storage structure may include lower electrodes electrically connected to the conductive regions, a support layer between the lower electrodes, the support layer having a support hole (i.e., opening), a dielectric layer covering the lower electrodes and the support layer, interface layers between the lower electrodes and the dielectric layer, a passivation layer between the support layer and the dielectric layer, and an upper electrode on the dielectric layer. In plan view, the passivation layer may extend along a side surface of the support layer exposed by the support, between the lower electrodes. The interface layers may extend along side surfaces of the lower electrodes exposed by the support hole.

According to another aspect of the present inventive concept, there is provided a semiconductor device including a lower structure having a conductive region, and an information storage structure on the lower structure. The information storage structure may include a lower electrode electrically connected to the conductive region, a first support layer and a second support layer on a side surface of the lower electrode, the second support layer below the first support layer, a dielectric layer covering the lower electrode, the first support layer, and the second support layer, an interface layer between the lower electrode and the dielectric layer, a first passivation layer between the first support layer and the dielectric layer, a second passivation layer between the second support layer and the dielectric layer, and an upper electrode on the dielectric layer. The interface layer may have a first portion in contact with an upper surface of the lower electrode and the first passivation layer, and a second portion between the first support layer and the second support layer.

### BRIEF DESCRIPTION OF THE DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a schematic plan view of a semiconductor device according to an example embodiment;

FIG. 2 is a schematic vertical cross-sectional view taken along lines II-I′ and II-II' of the semiconductor device illustrated in FIG. 1;

FIG. 3 is an enlarged view of a portion of the semiconductor device illustrated in FIG. 1;

FIGS. 4 and 5 are partially enlarged views of the semiconductor device illustrated in FIG. 2;

FIGS. 6 to 8 are schematic vertical cross-sectional views of semiconductor devices according to example embodiments;

FIG. 9 is a flowchart of a method of forming a semiconductor device according to an example embodiment;

FIGS. 10 to 16 are schematic vertical cross-sectional views of sequential intermediate processes of a method of manufacturing a semiconductor device according to an example embodiment;

FIG. 17 is a flowchart of a method of forming an interface layer according to an example embodiment;

FIGS. 18 to 20 are schematic vertical cross-sectional views of sequential intermediate processes of a method of forming an interface layer according to an example embodiment;

FIG. 21 is a flowchart of a method of forming an interface layer according to an example embodiment;

FIG. 22 illustrates concentrations of an interface layer according to comparative examples and examples of the present inventive concept;

FIG. 23 illustrates defect rates according to comparative examples and examples of the present inventive concept;

FIG. 24 is a schematic plan view of an integrated circuit device according to example embodiments; and

FIG. 25 is a schematic vertical cross-sectional view taken along lines X1-X1′ and Y1-Y1′ of the integrated circuit device illustrated in FIG. 24.

### DETAILED DESCRIPTION

Hereinafter, preferred example embodiments of the present inventive concept will be described with reference to the attached drawings.

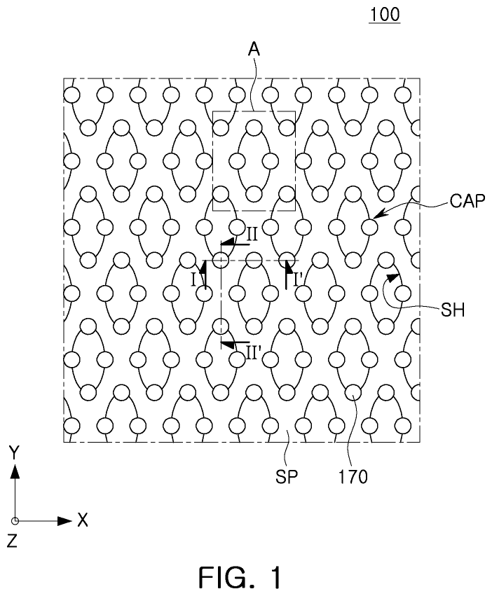

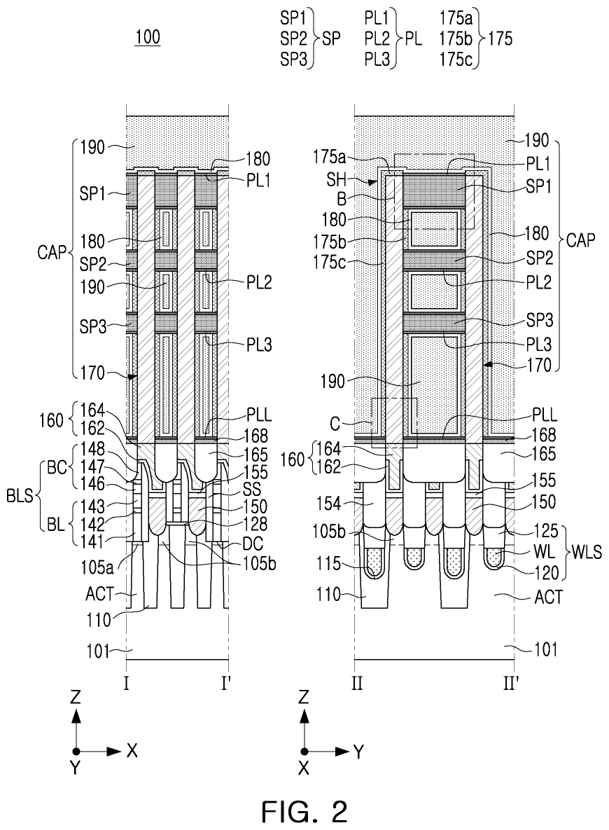

FIG. 1 is a schematic plan view of a semiconductor device according to an example embodiment. FIG. 2 is a schematic vertical cross-sectional view taken along lines I-I′ and II-II′ of the semiconductor device illustrated in FIG. 1.

Referring to FIGS. 1 and 2, a semiconductor device 100 may include a substrate 101 having active regions ACT, a device isolation layer 110 defining the active regions ACT in the substrate 101, a word line structure WLS buried in the substrate 101, the word line structure WLS including a word line WL, a bit line structure BLS extending to intersect the word line structure WLS on the substrate 101, the bit line structure BLS including a bit line BL, and an information storage structure CAP on the bit line structure BLS. The information storage structure CAP may store information, and may be, for example, a capacitor structure of a dynamic random access memory (DRAM). The semiconductor device 100 may further include a lower conductive pattern 150 on the active region ACT, an upper conductive pattern 160 on the lower conductive pattern 150, and an insulating pattern 165 passing through the upper conductive pattern 160.

The semiconductor device 100 may include, for example, a cell array of the DRAM. For example, the bit line BL may be connected to a first impurity region 105a of the active region ACT, and a second impurity region 105b of the active region ACT may be electrically connected to the information storage structure CAP on the upper conductive pattern 160 through the lower and upper conductive patterns 150 and 160.

The information storage structure CAP may be a capacitor capable of storing

information in a memory such as the DRAM. The information storage structure CAP may be electrically connected to the conductive regions 150 and 160, on a lower structure including the lower and upper conductive patterns 150 and 160. Here, the lower structure may include a substrate 101, a word line structure WLS, and a bit line structure BLS.

The information storage structure CAP may include lower electrodes 170, a dielectric layer 180 on the lower electrodes 170, interface layers 175 between the lower electrodes 170 and the dielectric layer 180, and an upper electrode 190 on the dielectric layer 180. The information storage structure CAP may further include support layers SP and passivation layers PL.

The semiconductor device 100 may include a cell array region in which a cell array is disposed, and a peripheral circuit region in which peripheral circuits for driving memory cells, disposed in the cell array, are disposed. The peripheral circuit region may be disposed around the cell array region.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on-insulator (GOI) substrate, a silicon-germanium substrate, or a substrate including an epitaxial layer.

Active regions ACT may be defined by the device isolation layer 110 in the substrate 101. The active region ACT may have a bar shape, and may be disposed to have an island shape extending in one direction in the substrate 101. The one direction may be inclined with respect to a direction in which the word lines WL and the bit lines BL extend. The active regions ACT may be disposed to be parallel to each other, and an end of one active region ACT may be disposed to be adjacent to the center of another active region ACT adjacent thereto.

The active region ACT may have first and second impurity regions 105a and 105b having a predetermined depth from an upper surface of the substrate 101. The first and second impurity regions 105a and 105b may be spaced apart from each other. The first and second impurity regions 105a and 105b may serve as source/drain regions of a transistor formed by the word line WL. The source region and the drain region, formed by the first and second impurity regions 105a and 105b caused by doping or ion implantation of substantially the same impurities, may be interchangeably referred to depending on a circuit configuration of a finally formed transistor. The impurities may include impurities having a conductivity type opposite to that of the substrate 101. In example embodiments, the depths of the first and second impurity regions 105a and 105b may be different from each other in the source region and the drain region.

The device isolation layer 110 may be formed using a shallow trench isolation (STI) process. The device isolation layer 110 may electrically isolate the active regions ACT from each other while surrounding the active regions ACT. The device isolation layer 110 may be made of an insulating material, for example, silicon oxide, silicon nitride, or a combination thereof. The device isolation layer 110 may have a plurality of regions having different lower end depths depending on a width of a trench in which the substrate 101 is etched.

The word line structures WLS may be disposed in gate trenches 115 extending in the substrate 101. Each of the word line structures WLS may include a gate dielectric layer 120, a word line WL, and a gate capping layer 125. As used herein, a “gate 120 and WL” may be referred to as a structure including the gate dielectric layer 120 and the word line WL, the word line WL may be referred to as a “gate electrode,” and the word line structure WLS may be referred to as a “gate structure.”

The word line WL may extend in a first direction X across the active region ACT. For example, a pair of word lines WL, adjacent to each other, may be disposed to cross one active region ACT. The word line WL may form a gate of a buried channel array transistor (BCAT), but the present inventive concept is not limited thereto. In example embodiments, the word lines WL may be disposed on an upper portion of the substrate 101. The word line WL may be disposed on a lower portion of a gate trench 115 to have a predetermined thickness. An upper surface of the word line WL may be positioned at a level lower than that of the upper surface of the substrate 101. As used herein, the high and the low of the term “level” may be defined based on a substantially flat (i.e., planar) upper surface of the substrate 101.

The word line WL may include a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). For example, the word line WL may include a lower pattern and an upper pattern, formed of different materials. The lower pattern may include at least one of tungsten (W), titanium (Ti), tantalum (Ta), tungsten nitride (WN), titanium nitride (TiN), and tantalum nitride (TaN). The upper pattern may be a semiconductor pattern including polysilicon doped with a P-type or N-type impurity.

The gate dielectric layer 120 may be disposed on a bottom surface and internal side surfaces (i.e., sidewalls) of the gate trench 115. The gate dielectric layer 120 may conformally cover an internal wall of the gate trench 115. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The term “cover” (or “covers” or “covering,” or like terms), as may be used herein, is intended to broadly refer to a material, layer or structure being on or over another material, layer or structure, but does not require the material, layer or structure to entirely cover the other material, layer or structure. The gate dielectric layer 120 may include at least one of silicon oxide, silicon nitride, and silicon oxynitride. The gate dielectric layer 120 may be, for example, a silicon oxide film or an insulating film having a high dielectric constant. In example embodiments, the gate dielectric layer 120 may be a layer formed by oxidizing the active region ACT or a layer formed by deposition.

The gate capping layer 125 may be disposed to fill the gate trench 115, on an upper portion of the word line WL. The term “fill” (or “filling,” “filled,” or like terms), as may be used herein, is intended to refer broadly to either completely filling a defined space (e.g., the gate trench 115) or partially filling the defined space; that is, the defined space need not be entirely filled but may, for example, be partially filled or have voids or other spaces throughout. An upper surface of the gate capping layer 125 may be positioned at a level substantially the same as that of the upper surface of the substrate 101; that is, the upper surface of the gate capping layer 125 may be coplanar with the upper surface of the substrate 101. The gate capping layer 125 may be formed of an insulating material, for example, silicon nitride.

The bit line structure BLS may extend in a direction, perpendicular to the word line WL, for example, a second direction Y. The bit line structure BLS may include a bit line BL, and a bit line capping pattern BC on the bit line BL.

The bit line BL may include a first conductive pattern 141, a second conductive pattern 142, and a third conductive pattern 143, sequentially stacked in the Z-direction (i.e., vertically). The bit line capping pattern BC may be disposed on the third conductive pattern 143. A buffer insulating layer 128 may be disposed between the first conductive pattern 141 and the substrate 101, and a portion of the first conductive pattern 141 (hereinafter, a bit line contact pattern DC) may be in contact with the first impurity region 105a of the active region ACT. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items. The bit line BL may be electrically connected to the first impurity region 105a through the bit line contact pattern DC. A lower surface of the bit line contact pattern DC may be positioned at a level lower than that of the upper surface of the substrate 101, and may be positioned at a level higher than that of the upper surface of the word line WL. In an example embodiment, the bit line contact pattern DC may be formed in the substrate 101 to be locally disposed in a bit line contact hole, exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer obtained by silicidizing a portion of the first conductive pattern 141. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), and aluminum (Al). In some example embodiments, the number of conductive patterns included in the bit line BL, a type of material, and/or a stacking order may be changed in various manners.

The bit line capping pattern BC may include a first capping pattern 146, a second capping pattern 147, and a third capping pattern 148, sequentially stacked on the third conductive pattern 143 in the Z-direction. Each of the first to third capping patterns 146, 147, and 148 may include an insulating material, for example, a silicon nitride film. The first to third capping patterns 146, 147, and 148 may be formed of different materials. Even when the first to third capping patterns 146, 147, and 148 include the same material, the first to third capping patterns 146, 147, and 148 may be distinguished from each other due to a difference in physical properties. A cross-sectional thickness of the second capping pattern 147 may be less than a cross-sectional thickness of the first capping pattern 146 and a cross-sectional thickness of the third capping pattern 148, respectively. In some example embodiments, the number of capping patterns and/or a type of material, included in the bit line capping pattern BC, may be changed in various manners.

Spacer structures SS may be disposed on opposite sidewalls of each of the bit line structures BLS to extend in a direction, for example, a Y-direction. The spacer structures SS may be disposed between the bit line structure BLS and the lower conductive pattern 150. The spacer structures SS may extend along sidewalls of the bit line BL and sidewalls of the bit line capping pattern BC. Fence insulating patterns 154 may be formed between the spacer structures SS. The fence insulating patterns 154 may include silicon nitride or silicon oxynitride. A pair of spacer structures SS, disposed on opposite sides of one bit line structure BLS, may have an asymmetric shape with respect to the bit line structure BLS. Each of the spacer structures SS may include a plurality of spacer layers, and may further include an air spacer in some example embodiments.

The lower conductive pattern 150 may be connected to one region of the active region ACT, for example, the second impurity region 105b. The lower conductive pattern 150 may be disposed between the bit lines BL and between the word lines WL. The lower conductive pattern 150 may pass through the buffer insulating layer 128 to be connected to the second impurity region 105b of the active region ACT. The lower conductive pattern 150 may be in direct contact with the second impurity region 105b. A lower surface of the lower conductive pattern 150 may be positioned at a level lower than that of the upper surface of the substrate 101, and may be positioned at a level higher than that of the lower surface of the bit line contact pattern DC. The lower conductive pattern 150 may be insulated from the bit line contact pattern DC by the spacer structure SS. The lower conductive pattern 150 may be formed of a conductive material. For example, the conductive material may include at least one of polycrystalline silicon (Si), titanium (Ti), titanium nitride (TiN), tantalum (Ta), tantalum nitride (TaN), tungsten (W), tungsten nitride (WN), and/or aluminum (Al), although embodiments are not limited thereto. In example embodiments, the lower conductive pattern 150 may include a plurality of layers.

A metal-semiconductor compound layer 155 may be disposed between the lower conductive pattern 150 and the upper conductive pattern 160. The metal-semiconductor compound layer 155 may be, for example, a layer obtained by silicidizing a portion of the lower conductive pattern 150, when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicides. In some example embodiments, the metal-semiconductor compound layer 155 may be omitted.

The upper conductive pattern 160 may be disposed on the lower conductive pattern 150. The upper conductive pattern 160 may extend between the spacer structures SS to cover an upper surface of the metal-semiconductor compound layer 155. The upper conductive pattern 160 may include a barrier layer 162 and a conductive layer 164. The barrier layer 162 may cover (e.g., conformally cover) a lower surface and side surfaces of the conductive layer 164. The barrier layer 162 may include a metal nitride, for example, at least one of titanium nitride (TiN), tantalum nitride (TaN), and/or tungsten nitride (WN), although embodiments are not limited thereto. The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and/or tungsten nitride (WN).

Insulating patterns 165 may be disposed between the upper conductive patterns 160. The insulating patterns 160 may electrically insulate the upper conductive patterns 160 from each other. The insulating patterns 165 may include an insulating material, for example, at least one of silicon oxide, silicon nitride, and/or silicon oxynitride.

The etch stop layer 168 may cover the insulating patterns 165, between the first electrode structures 170. The etch stop layer 168 may be in contact with lower regions of side surfaces of the first electrode structures 170. The etch stop layer 168 may be disposed below the support layers SP. The etch stop layer 168 may include, for example, at least one of silicon nitride (SiN), silicon oxynitride (SiON), silicon carbonitride (SiCN), and/or silicon boron nitride (SiBN).

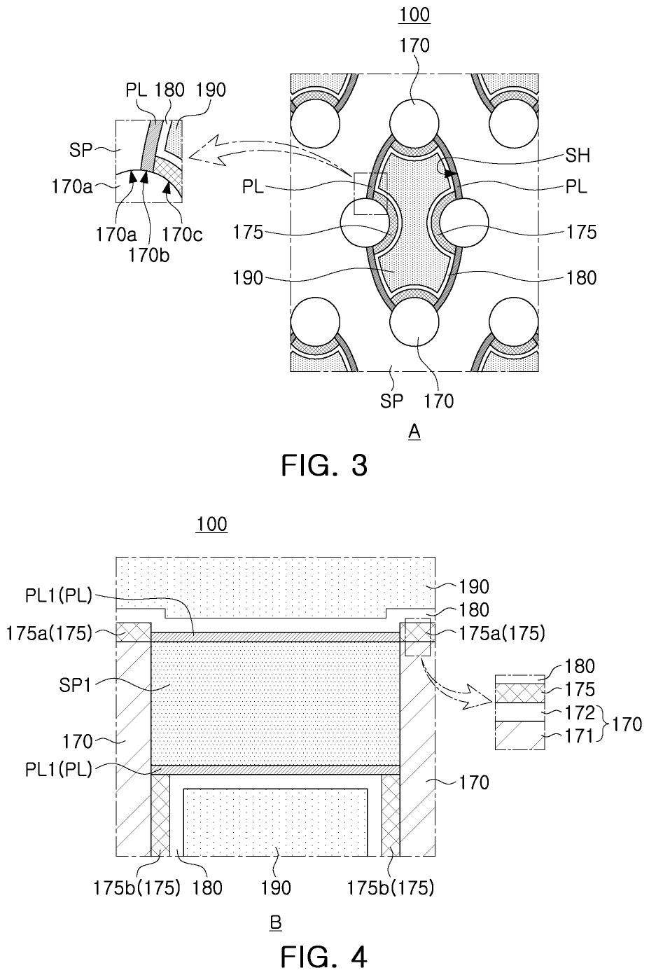

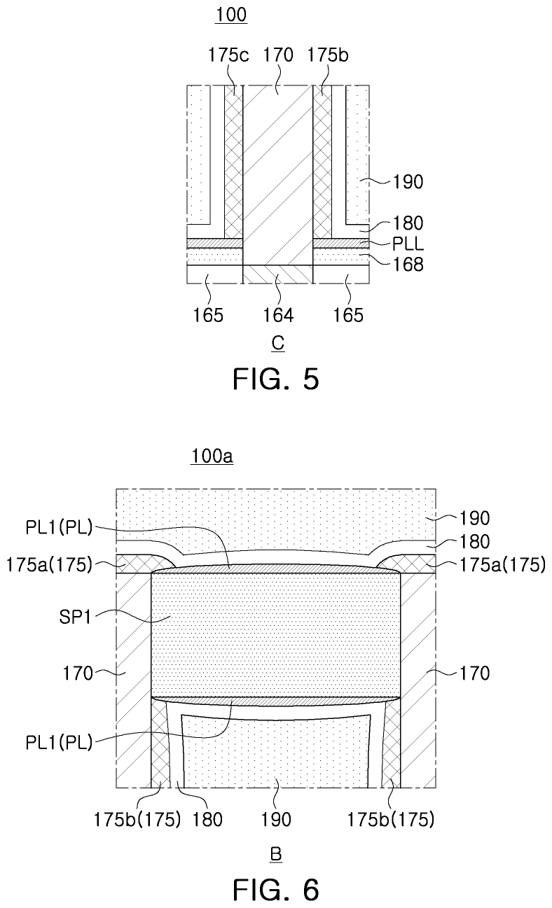

FIG. 3 is an enlarged view of a portion of the semiconductor device illustrated in FIG. 1. FIGS. 4 and 5 are partially enlarged views of the semiconductor device illustrated in FIG. 2.

Referring further to FIGS. 3 to 5, the lower electrodes 170 may be disposed on the upper conductive patterns 160. The lower electrodes 170 may have a pillar shape. The lower electrodes 170 may be spaced apart from each other in an X-direction and a Y-direction. In an example embodiment, the lower electrodes 170 may be arranged to have a honeycomb structure. For example, as illustrated in FIG. 1, the lower electrodes 170 may be disposed at vertices of a hexagonal pattern and the center of the hexagonal pattern, respectively.

As illustrated in FIG. 4, in an example embodiment, the lower electrode 170 may include a first layer 171 and a second layer 172. The second layer 172 may cover or surround the first layer 171, and may include metal oxide and metal oxynitride. For example, the first layer 171 may include at least one of vanadium nitride (VN), titanium nitride (TiN), titanium silicide nitride (TiSiN), niobium nitride (NbN), molybdenum nitride (MoN), tantalum nitride (TaN), ruthenium (Ru), ruthenium oxide (RuO2), platinum (Pt), iridium (Ir), strontium ruthenate (SrRuO₃), tungsten (W), and tungsten nitride (WN), although embodiments are not limited thereto. The second layer 172 may include at least one of niobium oxide (NbOx), niobium oxynitride (NbON), tantalum oxide (TaOx), and tantalum oxynitride (TaON).

The support layers SP may include a first support layer SP1, a second support layer SP2 disposed below the first support layer SP1, and a third support layer SP3 disposed below the second support layer SP2. The support layers SP1, SP2, and SP3 may be spaced apart from the substrate 101 in a Z-direction, perpendicular to an upper surface of the substrate 101. The support layers SP1, SP2, and SP3 may be in contact with the lower electrodes 170, and may extend in a direction (horizontal direction), parallel to the upper surface of the substrate 101.

The first support layer SP1 may have a cross-sectional thickness greater than those of the second support layer SP2 and the third support layer SP3, but the present inventive concept is not limited thereto. The support layers SP1, SP2, and SP3 may be layers supporting the lower electrodes 170 having a high aspect ratio. The support layers SP1, SP2, and SP3 may respectively include, for example, at least one of silicon nitride (SiN), silicon oxynitride (SiON), silicon carbonitride (SiCN), and/or silicon boron nitride (SiBN). In an example embodiment, the support layers SP1, SP2, and SP3 may include silicon carbonitride (SiCN). The number and cross-sectional thicknesses of the support layers SP1, SP2, and SP3, and/or an arrangement relationship between the support layers SP1, SP2, and SP3 are not limited to those illustrated, and may be changed in various manners in some example embodiments.

An upper surface of the first support layer SP1 may be coplanar with upper surfaces of the lower electrodes 170, relative to the upper surface of the substrate 101 as a reference layer.

As illustrated in FIG. 1, the support layers SP1, SP2, and SP3 may be disposed between the lower electrodes 170, and may support the lower electrodes 170. The support layers SP1, SP2, and SP3 may respectively include support holes SH. The support holes SH, formed in the support layers SP1, SP2, and SP3, may overlap each other in a vertical direction (i.e., Z-direction), but the present inventive concept is not limited thereto. The term “overlap” (or “overlapping,” or like terms), as may be used herein, is intended to broadly refer to a first element that intersects with at least a portion of a second element in the vertical direction (i.e., Z-direction), but does not require that the first and second elements be completely aligned with one another in a horizontal plane (i.e., in the X-direction and/or the Y-direction). FIG. 1 illustrates that the support holes SH are disposed between four adjacent lower electrodes 170, but the present inventive concept is not limited thereto. A shape and an arrangement method of the support hole SH may vary in some example embodiments.

The passivation layer PL may be disposed between the support layers SP1, SP2, and SP3 and the dielectric layer 180. The passivation layer PL may include a first passivation layer PL1, a second passivation layer PL2, and a third passivation layer PL3. The first passivation layer PL1 may cover the first support layer SP1. For example, in cross-sectional view, the first passivation layer PL1 may cover upper and lower surfaces of the first support layer SP1. In plan view, the first passivation layer PL1 may cover a side surface of the first support layer SP1 exposed by the support holes SH. The second passivation layer PL2 and the third passivation layer PL3 may have a structure the same as or similar to that of the first passivation layer PL1. For example, the second passivation layer PL2 may cover upper and lower surfaces of the second support layer SP2, and may cover a side surface of the second support layer SP2 exposed by the support holes SH. The first passivation layer PL1, the second passivation layer PL2, and the third passivation layer PL3 may also be in contact with a side surface of the lower electrode 170.

The passivation layer PL may include a material different from that of the support layer SP. For example, the passivation layer PL may include a halogen compound. The first passivation layer PL1, the second passivation layer PL2, and the third passivation layer PL3 may respectively include at least one of fluorine (F), chlorine (Cl), bromine (Br), and/or iodine (I).

The semiconductor device 100 may further include a lower passivation layer PLL, disposed on the etch stop layer 168. The lower passivation layer PLL may be disposed between the etch stop layer 168 and the dielectric layer 180. The lower passivation layer PLL may be in contact with lower regions of side surfaces of the lower electrodes 170. The lower passivation layer PLL may include a halogen compound.

The interface layer 175 may be disposed between the lower electrode 170 and the dielectric layer 180. The interface layer 175 may include a first portion 175a, a second portion 175b, and a third portion 175c. The first portion 175a of the interface layer 175 may cover an upper surface of the lower electrode 170, and may extend in a horizontal direction. The first portion 175a of the interface layer 175 may be in contact with a side surface of the first passivation layer PL1. It is illustrated that a thickness of the first portion 175a of the interface layer 175 is greater than a thickness of the first passivation layer PL1, but the present inventive concept is not limited thereto.

The second portion 175b of the interface layer 175 may cover the side surface of the lower electrode 170, and may extend in the vertical direction. The second portions 175b may be respectively in contact with an upper surface or a lower surface of at least one of the first passivation layer PL1, the second passivation layer PL2, and the third passivation layer PL3. The second portions 175b may overlap the support layers SP1, SP2, and SP3 in the vertical direction (i.e., Z-direction).

The third portion 175c of the interface layer 175 may cover the side surface of the lower electrode 170 exposed by the support holes SH, and may extend in the vertical direction. The second portion 175b and the third portion 175c of the interface layer 175 may be in contact with an upper surface of the lower passivation layer PLL. Lower surfaces of the second portion 175b and the third portion 175c may be respectively positioned at a level higher than that of a lower surface of the lower electrode 170.

The interface layer 175 may include a conductive material. In an example embodiment, the interface layer 175 may include metal oxide or metal oxynitride, and may include, as a metal element, at least one of scandium (Sc), yttrium (Y), titanium (Ti), vanadium (V), niobium (Nb), tantalum (Ta), chromium (Cr), molybdenum (Mo), tungsten (W), iron (Fe), ruthenium (Ru), osmium (Os), cobalt (Co), rhodium (Rh), iridium (Ir)), boron (B), tin (Sn), platinum (Pt), and/or lanthanum (La). In an example embodiment, the interface layer 175 may include at least one of niobium oxide (NbOx) and tantalum oxide (TaOx). The interface layer 175 may improve capacitance of the information storage structure CAP.

The dielectric layer 180 may cover the lower electrodes 170 and the support layers SP1, SP2, and SP3. The dielectric layer 180 may be disposed between the lower electrodes 170 and the upper electrode 190. The dielectric layer 180 may be in contact with the passivation layer PL and the interface layer 175.

The dielectric layer 180 may include a high dielectric constant (high-K) material, silicon oxide, silicon nitride, or a combination thereof. However, in some example embodiments, the dielectric layer 180 may include oxide, nitride, silicide, oxynitride, or silicon oxynitride including at least one or combinations of titanium (Ti), tantalum (Ta), hafnium (Hf), aluminum (Al), zirconium (Zr), and/or lanthanum (La), doped with fluorine (F). The dielectric layer 180 may further include one or more elements, among aluminum (Al), yttrium (Y), vanadium (V), and silicon (Si), in the form of a solid solution or an oxide film. In an example embodiment, the semiconductor device 100 may further include a capping layer disposed on an upper surface or a lower surface of the dielectric layer 180, or may further include an insertion film disposed in the dielectric layer 180. Main elements of the capping layer and the insertion layer may include at least one of silicon (Si), boron (B), lithium (Li), scandium (Sc), strontium (Sr), aluminum (Al), yttrium (Y), niobium (Nb), tantalum (Ta), titanium (Ti), molybdenum (Mo), and lanthanum (La).

The upper electrode 190 may cover a plurality of lower electrodes 170, the support layers SP1, SP2, and SP3, and the dielectric layer 180. The upper electrode 190 may at least partially fill a space between the plurality of lower electrodes 170, and a space between the support layers SP1, SP2, and SP3. The upper electrode 190 may be in direct contact with the dielectric layer 180. In an example embodiment, the upper electrode 190 may include at least one of TiN, NbN, WN, VN, MON, TaN, TiSiN, TiCN, a silicon material, and a silicon-germanium material.

Referring further to FIG. 3, in plan view, a side surface of the support layer SP and side surfaces of the lower electrodes 170 may be exposed by the support hole SH. The passivation layers PL may extend along an internal wall of the support hole SH, between the lower electrodes 170. For example, the passivation layers PL may extend along the side surface of the support layer SP exposed by the support hole SH, and may have an arc shape. The interface layers 175 may extend along the internal wall of the support hole SH, between the passivation layers PL. For example, the interface layers 175 may extend along the side surfaces of the lower electrodes 170 exposed by the support hole SH, and may have an arc shape. The lower electrodes 170 may respectively have a first portion 170a not exposed by the support hole SH, and a second portion 170b and a third portion 170c exposed by the support hole SH. The first portion 170a may be in contact with the support layer SP, the second portion 170b may be in contact with the passivation layer PL, and the third portion 170c may be in contact with the interface layer 175. The second portion 170b may be disposed between the first portion 170a and the third portion 170c. In plan view, a portion of the passivation layers PL may be in contact with the interface layers 175. For example, a portion of the passivation layers PL may be covered by the interface layers 175 and spaced apart from the dielectric layer 180.

FIGS. 6 to 8 are schematic vertical cross-sectional views of semiconductor devices according to example embodiments.

Referring to FIG. 6, a semiconductor device 100a may include a passivation layer PL (PL1) on a support layer SP (SP1), and an interface layer 175 (175a) on a lower electrode 170. In an example embodiment, the passivation layer PL may not have a constant cross-sectional thickness. For example, the thickness of the passivation layer PL may decrease as a distance from the lower electrode 170 decreases. In an example embodiment, a portion of the interface layer 175 may overlap the passivation layer PL in a vertical direction (i.e., Z-direction). The interface layer 175 may not have a constant cross-sectional thickness. A portion of the interface layer 175 may extend onto the support layer SP and cover the passivation layer PL. The cross-sectional thickness of the interface layer 175 may decrease as a distance from the support layer SP decreases.

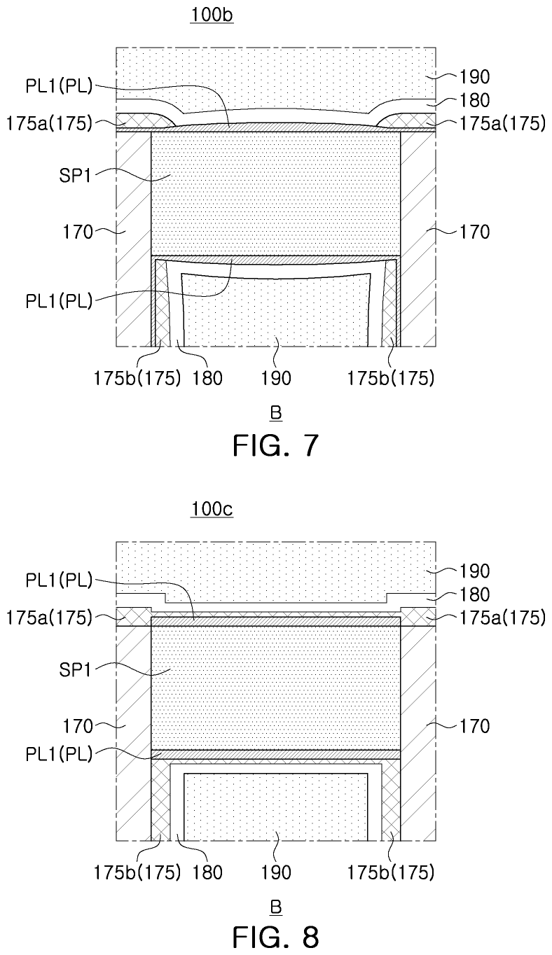

Referring to FIG. 7, a semiconductor device 100b may include a passivation layer PL on a support layer SP, and an interface layer 175 on a lower electrode 170. In an example embodiment, the passivation layer PL may extend further onto the lower electrode 170. For example, a portion of the passivation layer PL may be in contact with the lower electrode 170, and may be disposed between the interface layer 175 and the lower electrode 170.

Referring to FIG. 8, a semiconductor device 100c may include a passivation layer PL on a support layer SP, and an interface layer 175 on a lower electrode 170. In an example embodiment, the interface layer 175 may extend further onto the passivation layer PL. For example, the passivation layer PL may be covered by the interface layer 175, and the interface layer 175 may extend in a horizontal direction, between adjacent lower electrodes 170. In an example embodiment, a cross-sectional thickness of a portion of the interface layer 175, covering the passivation layer PL, may be less than a cross-sectional thickness of a portion of the interface layer 175, covering the lower electrodes 170. The interface layer 175 may be interposed between the passivation layer PL and a dielectric layer 180, and the passivation layer PL may be spaced apart from the dielectric layer 180.

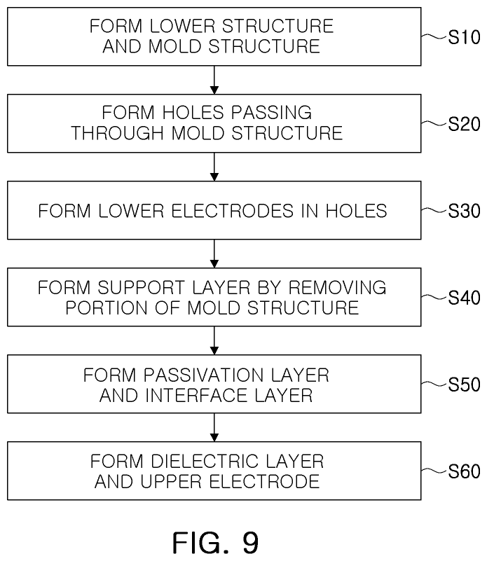

FIG. 9 is a flowchart of a method of forming a semiconductor device according to an example embodiment.

Referring to FIG. 9, a method of manufacturing a semiconductor device according to an example embodiment may include forming a lower structure and a mold structure on a substrate (S10), forming a plurality of holes passing through the mold structure (S20), forming lower electrodes in a plurality of holes (S30), removing a portion of the mold structure to form a support layer (S40), forming a passivation layer on the support layer and forming an interface layer on the lower electrodes (S50), and forming a dielectric layer and an upper electrode (S60).

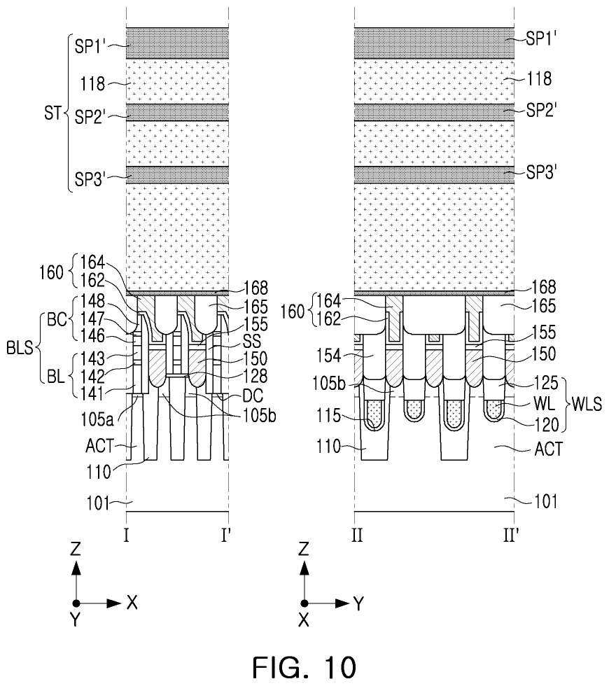

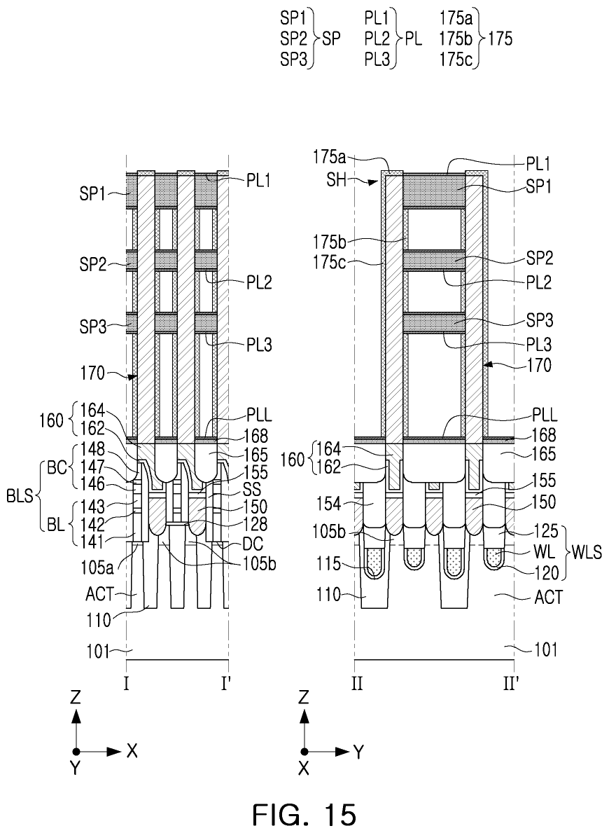

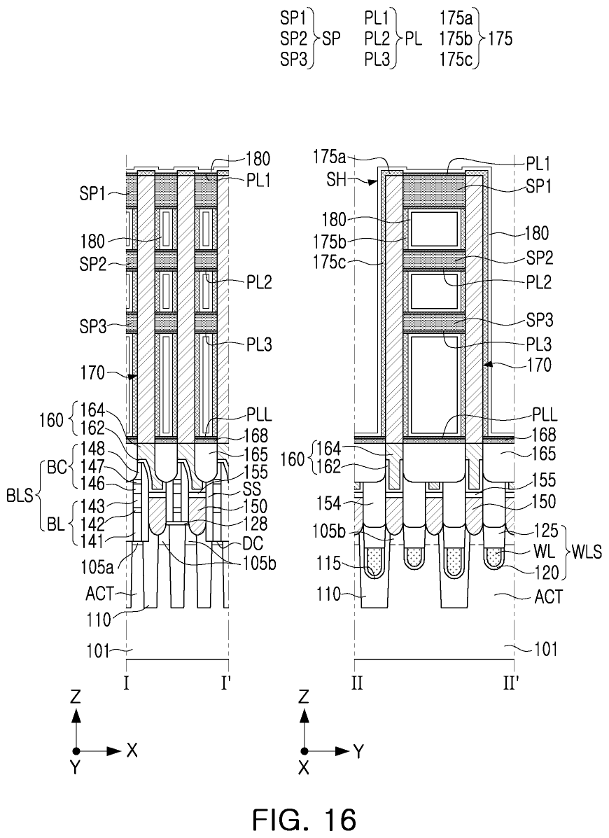

FIGS. 10 to 16 are schematic vertical cross-sectional views of sequential intermediate processes of a method of manufacturing a semiconductor device according to an example embodiment.

Referring to FIGS. 9 and 10, a lower structure and a mold structure ST may be formed on a substrate (S10). First, a device isolation layer 110 may be formed on a substrate 101 to define an active region ACT. A device isolation trench may be formed in the substrate 101, and the device isolation layer 110 may fill the device isolation trench. In plan view, the active region ACT may have a shape of an elongated bar extending in a direction, diagonal to a direction in which a word line WL extends. An ion implantation process may be performed using the device isolation layer 110 as an ion implantation mask to form impurity regions on an upper portion of the active region ACT. A gate trench 115 may be formed by patterning the active region ACT and the device isolation layer 110. A pair of gate trenches 115 may cross the active region ACT, but the present inventive concept is not limited thereto. The impurity regions may also be isolated from each other by the gate trench 115 to form a first impurity region 105a and a second impurity region 105b.

A gate dielectric layer 120 may be formed on an internal surface of the gate trench 115 to have a substantially conformal (i.e., uniform) thickness. Subsequently, the word line WL may be formed to fill at least a portion of the gate trench 115. An upper surface of the word line WL may be recessed to be lower than an upper surface of the active region ACT. An insulating layer may be stacked on the substrate 101 to fill the gate trench 115 and then etched to form a gate capping layer 125 on the word line WL.

An insulating layer and a conductive layer may be sequentially formed and patterned on a front surface of the substrate 101 to form a buffer insulating layer 128 and a first conductive pattern 141, sequentially stacked. The buffer insulating layer 128 may be formed of at least one of silicon oxide, silicon nitride, and silicon oxynitride. A plurality of buffer insulating layers 128 may be spaced apart from each other. The first conductive pattern 141 may have a shape corresponding to a planar shape of the buffer insulating layer 128. The buffer insulating layer 128 may be formed to simultaneously cover ends of two adjacent active regions ACT, that is, adjacent second impurity regions 105b. A bit line contact hole may be formed by etching upper portions of the device isolation layer 110, the substrate 101, and the gate capping layer 125 using the buffer insulating layer 128 and the first conductive pattern 141 as an etching mask. The bit line contact hole may expose the first impurity region 105a.

A bit line contact pattern DC, filling the bit line contact hole, may be formed. Forming the bit line contact pattern DC may include forming a conductive layer filling the bit line contact hole, and performing a planarization process. For example, the bit line contact pattern DC may be formed of polysilicon. After sequentially forming a second conductive pattern 142, a third conductive pattern 143, and first to third capping patterns 146, 147, and 148, respectively, on a first conductive pattern 141, the first to third conductive patterns 141, 142, and 143 may be sequentially etched using the first to third capping patterns 146, 147, and 148 as an etching mask. As a result, a bit line structure BLS, including a bit line BL including the first to third conductive patterns 141, 142, and 143 and a bit line capping pattern BC including the first to third capping patterns 146, 147, and 148, may be formed.

A spacer structure SS may be formed on side surfaces (extending in the Z-direction) of the bit line structure BLS. The spacer structure SS may be formed of a plurality of layers. Fence insulating patterns 154 may be formed between the spacer structures SS. The fence insulating patterns 154 may include silicon nitride or silicon oxynitride, although embodiments are not limited thereto. An opening, exposing the second impurity region 105b, may be formed by performing an anisotropic etching process using the fence insulating patterns 154 and the third capping pattern 148 as an etching mask.

A lower conductive pattern 150 may be formed on a lower portion of the opening. The lower conductive pattern 150 may be formed of a semiconductor material such as polysilicon. For example, the lower conductive pattern 150 may be formed by forming a polysilicon layer, filling the opening, and then performing an etch-back process.

A metal-semiconductor compound layer 155 may be formed on the lower conductive pattern 150. The formation of the metal-semiconductor compound layer 155 may include a metal layer deposition process and a heat treatment process, to thereby form a metal silicide.

An upper conductive pattern 160 may be formed on an upper portion of the opening. Forming the upper conductive pattern 160 may include sequentially forming a barrier layer 162 and a conductive layer 164. Thereafter, a patterning process may be performed on the barrier layer 162 and the conductive layer 164 to form insulating patterns 165 passing therethrough. Accordingly, a lower structure, including the substrate 101, a word line structure WLS, and the bit line structure BLS, may be formed.

An etch stop layer 168 may be conformally formed on the lower structure, and mold layers 118 and preliminary support layers SP1′, SP2′, and SP3′ may be alternately stacked on the etch stop layer 168. The mold layers 118 and the preliminary support layers SP1′, SP2′, and SP3′ may be included in the mold structure ST. The etch stop layer 168 may include the mold layers 118 and an insulating material having an etch selectivity under a specific etch condition, for example, at least one of silicon oxide, silicon nitride, silicon carbide, silicon oxycarbide, and silicon carbonitride. The mold layers 118 may be formed of silicon oxide, and the preliminary support layers SP1′, SP2′, and SP3′ may be formed of at least one of silicon nitride, silicon oxynitride, silicon carbonitride, and silicon boron nitride.

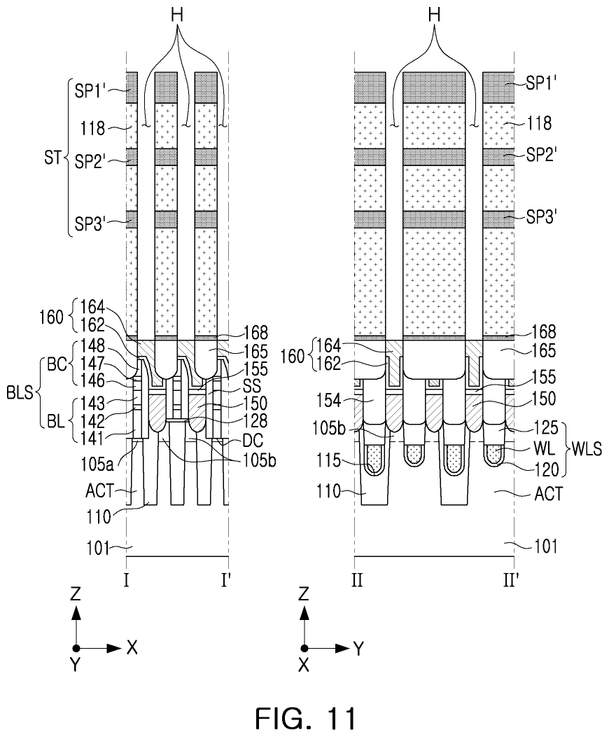

Referring to FIGS. 9 and 11, a plurality of holes H, passing through the mold structure ST, may be formed (S20). An anisotropic etching process may be performed to form the plurality of holes H, and the etch stop layer 168 may serve as a stopper for stopping an etching process. The plurality of holes H may pass through the etch stop layer 168 to expose upper conductive patterns 160. The plurality of holes H, regions in which lower electrodes 170 are to be formed, may be spaced apart from each other at predetermined intervals on a plane so as to be formed in a regular arrangement, as illustrated in FIG. 1.

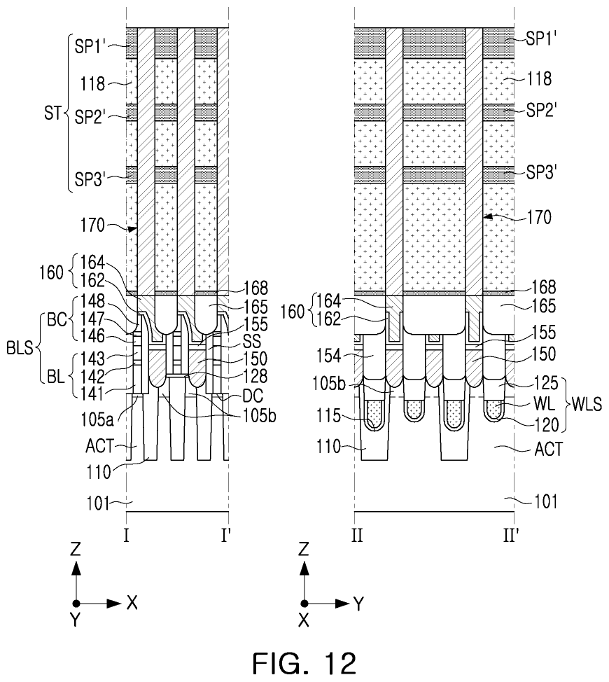

Referring to FIGS. 9 and 12, lower electrodes 170 may be formed in the plurality of holes H (see FIG. 11) (S30). The lower electrodes 170 may be formed by depositing a conductive material to fill the plurality of holes H and etching back or planarizing the conductive material to expose an upper surface of the mold structure ST.

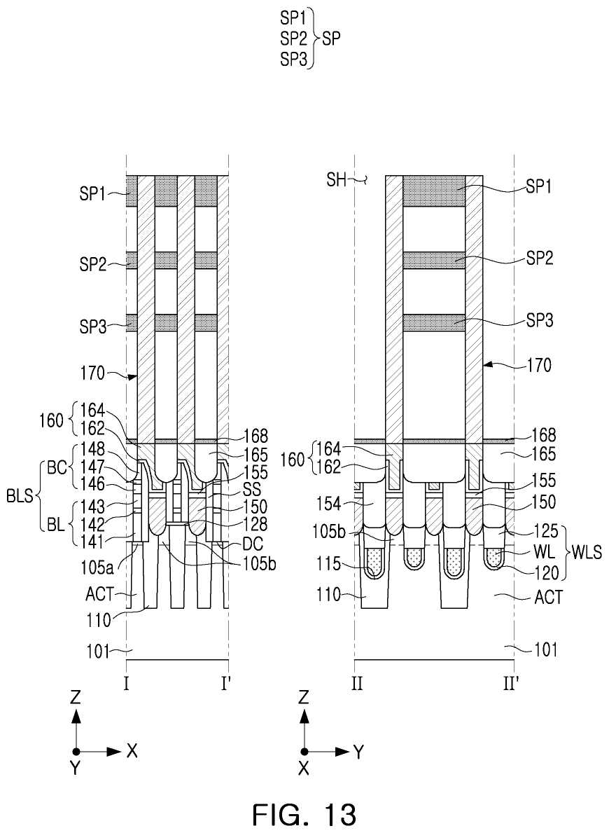

Referring to FIGS. 9 and 13, support layers SP1, SP2, and SP3, including a support hole SH, may be formed by removing a portion of the mold structure ST (S40). In an example embodiment, the support layers SP1, SP2, and SP3 may include support holes SH having the same pattern, but the present inventive concept is not limited thereto. A side surface of the lower electrode 170 may be exposed by selectively removing the mold layers 118 (see FIG. 12) between the support layers SP1, SP2, and SP3. In example embodiments, a process of removing the mold layers 118 may be performed, for example, using a wet etching process using an etchant (for example, a hydrogen fluoride (HF) solution).

Referring to FIGS. 9, 14, and 15, a passivation layer PL and an interface layer 175 may be formed (S50 and S60). The passivation layer PL may be formed on the support layer SP. In an example embodiment, a lower passivation layer PLL may be formed on the etch stop layer 168. Forming the passivation layer PL may include supplying a halogen element, and the passivation layer PL may include a halogen compound. In an example embodiment, the passivation layer PL may be selectively deposited only on a surface of the support layer SP, but the present inventive concept is not limited thereto. In some example embodiments, as illustrated in FIG. 7, the passivation layer PL may also be formed on surfaces of the lower electrodes 170.

The interface layer 175 may be formed on the lower electrodes 170. In an example embodiment, the interface layer 175 may be selectively deposited only on the surfaces of the lower electrodes 170, but the present inventive concept is not limited thereto. In some example embodiments, as illustrated in FIG. 8, the interface layer 175 may also be formed on a surface of the passivation layer PL.

Referring to FIGS. 9, 16, and 2, a dielectric layer 180 and an upper electrode 190 may be sequentially formed on the passivation layer PL and the interface layer 175 (S60). The dielectric layer 180 may cover an upper surface and a lower surface of each of the passivation layer PL and the interface layer 175.

A semiconductor device 100 may be manufactured by forming the upper electrode 190 on the dielectric layer 180. The upper electrode 190 may fill a space between the lower electrodes 170.

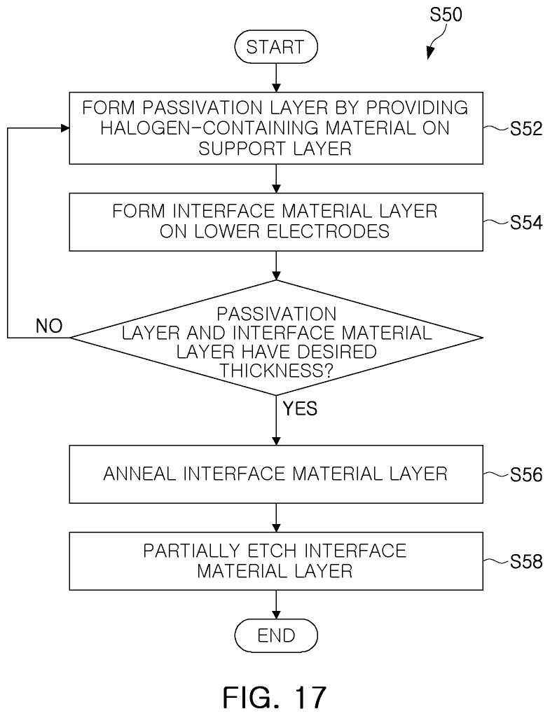

FIG. 17 is a flowchart of a method of forming an interface layer according to an example embodiment.

Referring to FIG. 17, forming a passivation layer PL and an interface layer 175 (S50) may include forming the passivation layer PL by providing a halogen-containing material on a support layer SP (S52), forming an interface material layer on the lower electrodes 170 (S54), when the passivation layer PL and the interface material layer have a desired thickness, annealing the interface material layer (S56), and partially etching the interface material layer (S58). When the passivation layer PL and the interface material layer do not have a desired thickness, the process of forming the passivation layer PL (S52) and forming the interface material layer (S54) are repeated until the desired thickness is reached.

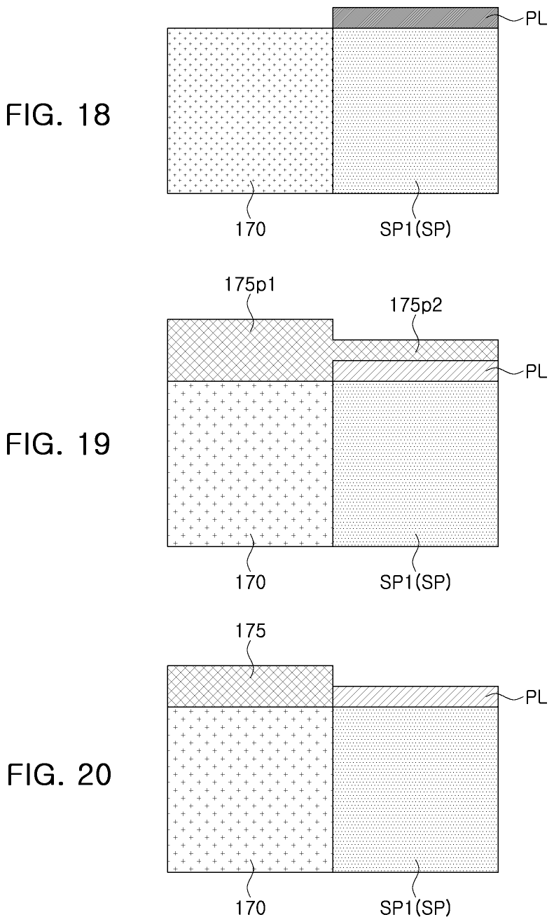

FIGS. 18 to 20 are schematic vertical cross-sectional views of sequential intermediate processes of a method of forming an interface layer according to an example embodiment.

Referring to FIGS. 17 and 18, a passivation layer PL may be formed by providing a halogen-containing material on a support layer SP (S52). For example, the halogen-containing material may include at least one of fluorine (F), chlorine (Cl), bromine (Br), and iodine (I). The halogen-containing material may be provided on the support layer SP in a liquid or gaseous state. For example, the halogen-containing material may include at least one of NF₃, HF, and ClF₃. When the halogen-containing material is a gas, the halogen-containing material may be provided in a thermal or plasma atmosphere, for example, of about 215° C. to about 460° C. The passivation layer PL may include a halogen compound.

Referring to FIGS. 17 and 19, an interface material layer 175p1 may be formed on lower electrodes 170 (S54). In an example embodiment, an interface material layer 175p2 may also be formed on the passivation layer PL. However, since the passivation layer PL includes the halogen compound, a deposition rate of the interface material layer 175p2 on the passivation layer PL may be less than a deposition rate of the interface material layer 175p1 on the lower electrodes 170. For example, a cross-sectional thickness of the interface material layer 175p2 may be less than a cross-sectional thickness of the interface material layer 175p1. In some example embodiments, the interface material layer 175p2 may not be formed on the passivation layer PL, and the interface material layer 175p1 may be selectively formed only on the lower electrodes 170.

Subsequently, the interface material layers 175p1 and 175p2 may be annealed (S56). Elements, included in the interface material layer 175p1, may permeate into the lower electrodes 170 using an annealing process. For example, as illustrated in FIG. 4, a second layer 172 of the lower electrode 170 may be formed using the annealing process.

Referring to FIGS. 17 and 20, the interface material layers 175p1 and 175p2 (see FIG. 19) may be partially etched (S58). The interface material layer 175p1 (FIG. 19) may be partially etched on the lower electrodes 170 to form the interface layer 175 using an etching process. The interface material layer 175p2 (FIG. 19) on the passivation layer PL may be removed using the etching process.

As illustrated in FIGS. 17 to 20, the passivation layer PL may be selectively formed on the support layer SP, such that a cross-sectional thickness of the interface layer 175 formed on the support layer SP may need to be reduced, or the interface layer 175 on the support layer SP may not be formed, thereby reducing or preventing electrical bridging in which the lower electrodes 170 are electrically connected to each other by the interface layer 175.

As illustrated in FIG. 17, forming the passivation layer PL (S52) and forming the interface material layers 175p1 and 175p2 (S54) may be performed a plurality of times until the passivation layer PL or the interface material layers 175p1 and 175p2 has a desired thickness. In some example embodiments, the interface material layer 175p2 may not be formed on the passivation layer PL, and the process (S58) of partially etching the interface material layer 175p1 may be omitted.

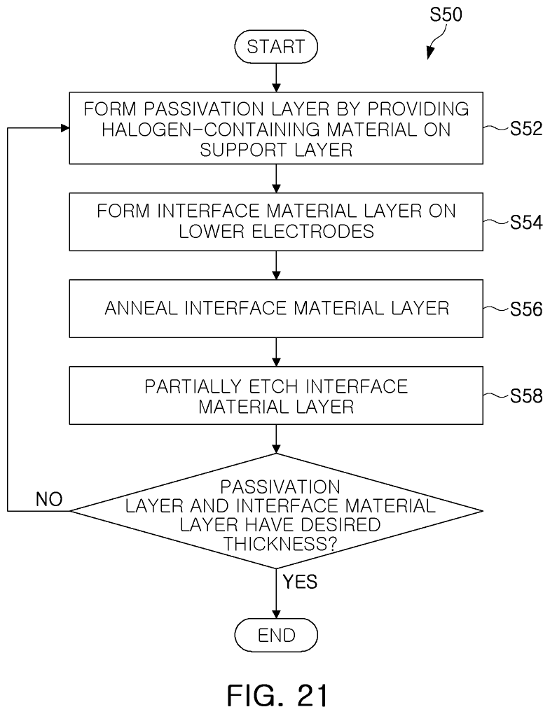

FIG. 21 is a flowchart of a method of forming an interface layer (S50) according to an example embodiment.

Referring to FIG. 21, unlike the method of forming an interface layer illustrated in FIG. 17, providing a halogen-containing material on a support layer SP to form a passivation layer PL (S52), forming an interface material layer on lower electrodes 170 (S54), annealing the interface material layer (S56), and partially etching the interface material layer (S58) may be performed a plurality of times until the passivation layer PL or an interface layer 175 has a desired thickness.

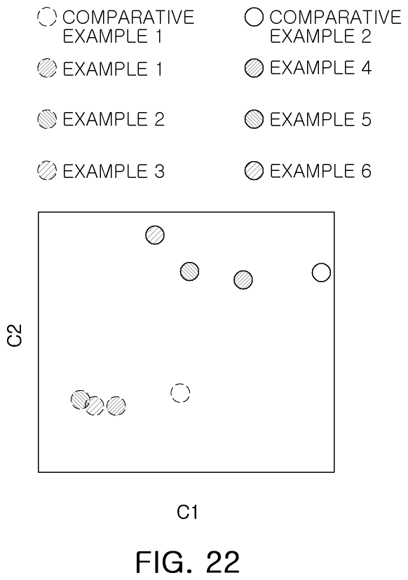

FIG. 22 illustrates concentrations of an interface layer according to comparative examples and examples of the present inventive concept. “C1” may refer to a concentration of an interface layer 175 on a surface of a support layer SP, measured, for example, using an X-ray photoelectron spectroscopy (XPS). “C2” may refer to a concentration of an interface layer 175 on a surface of a lower electrode 170 measured, for example, using the XPS.

Referring to FIG. 22, in Comparative Example 1, a process of depositing an interface layer 175 without forming a passivation layer PL was performed twice. In Examples 1, 2, and 3 of the present inventive concept, a process of forming a passivation layer PL and depositing an interface layer 175 was performed twice. A thickness of the passivation layer PL in Example 2 may be greater than a thickness of the passivation layer PL in Example 1, and may be less than a thickness of the passivation layer PL in Example 3.

A concentration of an interface layer 175 on a surface of an support layer SP in Examples 1 to 3 may be low, as compared to Comparative Example 1, thereby reducing or preventing electrical bridging between lower electrodes 170. In addition, as a thickness of the passivation layer PL increases, the concentration of the interface layer 175 on the surface of the support layer SP may decrease.

In Comparative Example 2, a process of depositing an interface layer 175 without forming a passivation layer PL was performed three times. In Examples 4, 5, and 6 of the present inventive concept, a process of forming a passivation layer PL and depositing an interface layer 175 was performed three times. A thickness of the passivation layer PL in Example 5 may be greater than a thickness of the passivation layer PL in Example 4, and may be less than the thickness of the passivation layer PL in Example 6.

A concentration of an interface layer 175 on a surface of an support layer SP in Examples 4 to 6 may be low, as compared to Comparative Example 2, thereby reducing or preventing electrical bridging between lower electrodes 170. In addition, as a thickness of the passivation layer PL increases, a concentration of the interface layer 175 on the surface of the support layer SP may decrease.

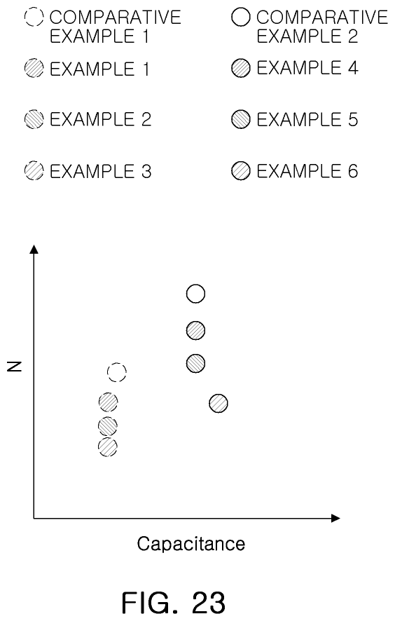

FIG. 23 illustrates defect rates according to comparative examples and examples of the present inventive concept. “Capacitance” may refer to a capacitance of an information storage structure CAP, and “N” may refer to a defect rate of the information storage structure CAP, for example, the number of times electrical bridging occurs between lower electrodes 170.

Referring to FIG. 23, as compared to Comparative Example 1, electrical bridging between lower electrodes 170 in Examples 1 to 3 may be reduced. In addition, as a thickness of a passivation layer PL increases, a defect rate of an information storage structure CAP may decrease.

As compared to Comparative Example 2, electrical bridging between lower electrodes 170 in Examples 4 to 6 may be reduced. In addition, as a thickness of a passivation layer PL increases, a defect rate of an information storage structure CAP may decrease and a capacitance of the information storage structure CAP may increase.

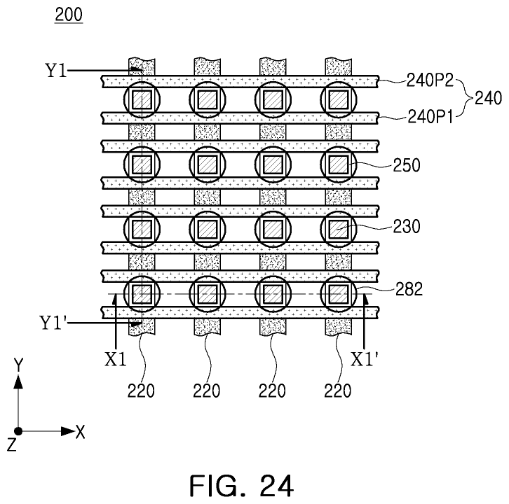

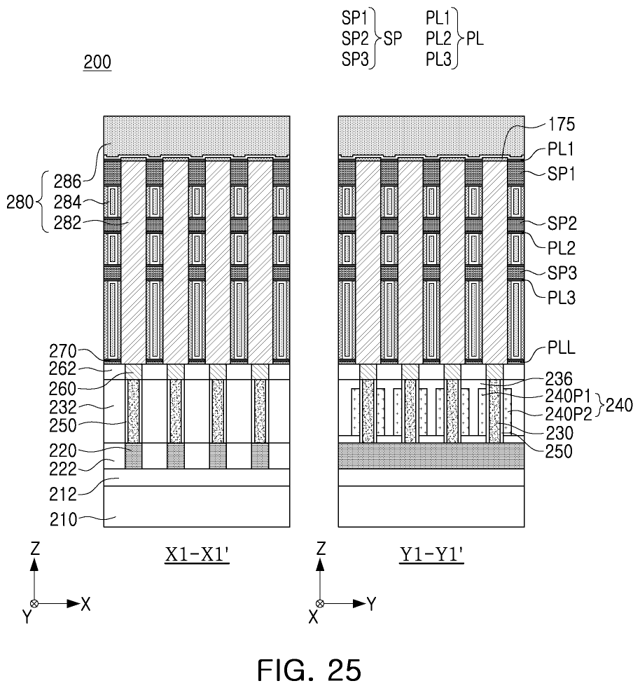

FIG. 24 is a schematic plan view of an integrated circuit device according to example embodiments. FIG. 25 is a vertical cross-sectional view taken along lines X1-X1′ and Y1-Y1′ of the integrated circuit device illustrated in FIG. 24.

Referring to FIGS. 24 and 25, an integrated circuit device 200 may include a substrate 210, a plurality of first conductive lines 220, a channel layer 230, a gate electrode 240, a gate insulating layer 250, and an information storage structure 280. The integrated circuit device 200 may be a memory device including a vertical channel transistor (VCT). The vertical channel transistor may refer to a structure in which a channel length of the channel layer 230 extends from the substrate 210 in a vertical direction (i.e., Z-direction).

A lower insulating layer 212 may be disposed on the substrate 210. On the lower insulating layer 212, the plurality of first conductive lines 220 may be spaced apart from each other in a first direction (X-direction) and may extend in a second direction (Y-direction). A plurality of first insulating patterns 222 may be disposed on the lower insulating layer 212 to fill a space between the plurality of first conductive lines 220. The plurality of first insulating patterns 222 may extend in the second direction (Y-direction), and upper surfaces of the plurality of first insulating patterns 222 may be disposed at a level the same as that of each of upper surfaces of the plurality of first conductive lines 220; that is, the upper surfaces of the first insulating patterns 222 may be coplanar with the upper surfaces of the first conductive lines 220, relative to an upper surface of the substrate 210 as a reference layer. The plurality of first conductive lines 220 may function as bit lines of the integrated circuit device 200.

In example embodiments, the plurality of first conductive lines 220 may include doped polysilicon, a metal, a conductive metal nitride, a conductive metal silicide, a conductive metal oxide, or combinations thereof, although embodiments are not limited thereto. For example, the plurality of first conductive lines 220 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof, but the present inventive concept is not limited thereto. The plurality of first conductive lines 220 may include a single layer or multiple layers formed of the above-described materials. In example embodiments, the plurality of first conductive lines 220 may include a two-dimensional (2D) semiconductor material. For example, the 2D semiconductor material may include graphene, carbon nanotubes, or a combination thereof.

The channel layer 230 may be arranged on the plurality of first conductive lines 220 in a matrix form of being spaced apart from each other in the first direction (X-direction) and the second direction (Y-direction). The channel layer 230 may have a first width in the first direction (X-direction) and a first height in a third direction (Z-direction), and the first height may be greater than the first width. For example, the first height may be about 2 to 10 times the first width, but the present inventive concept is not limited thereto. A bottom portion of the channel layer 230 may function as a first source/drain region (not illustrated), an upper portion of the channel layer 230 may function as a second source/drain region (not illustrated), and a portion of the channel layer 230 between the first and second source/drain regions may function as a channel region (not illustrated). The first source/drain region and the second source/drain region may be vertically spaced apart from each other, and the channel region may be a vertical channel region.

In example embodiments, the channel layer 230 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof. The channel layer 230 may include a single layer or multiple layers of the oxide semiconductor. In some examples, the channel layer 230 may have a bandgap energy greater than that of silicon. For example, the channel layer 230 may have a bandgap energy of about 1.5 eV to about 5.6 eV. For example, the channel layer 230 may have optimal channel performance when the channel layer 230 has a bandgap energy of about 2.0 eV to 4.0 eV. For example, the channel layer 230 may be polycrystalline or amorphous, but the present inventive concept is not limited thereto. In example embodiments, the channel layer 230 may include a 2D semiconductor material. For example, the 2D semiconductor material may include graphene, carbon nanotubes, or a combination thereof.

The gate electrode 240 may extend on opposite sidewalls of the channel layer 230 in the first direction (X-direction). The gate electrode 240 may include a first sub-gate electrode 240P1 opposing a first sidewall of the channel layer 230, and a second sub-gate electrode 240P2 opposing a second sidewall opposite to the first sidewall of the channel layer 230. As one channel layer 230 is disposed between the first sub-gate electrode 240P1 and the second sub-gate electrode 240P2, the integrated circuit device 200 may have a dual-gate transistor structure. However, the present inventive concept is not limited thereto, and the second sub-gate electrode 240P2 may be omitted, and only the first sub-gate electrode 240P1 opposing the first sidewall of the channel layer 230 may be formed to implement a single gate transistor structure.

The gate electrode 240 may include doped polysilicon, a metal, a conductive metal nitride, a conductive metal silicide, a conductive metal oxide, or combinations thereof. For example, the gate electrode 240 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or combinations thereof, but the present inventive concept is not limited thereto.

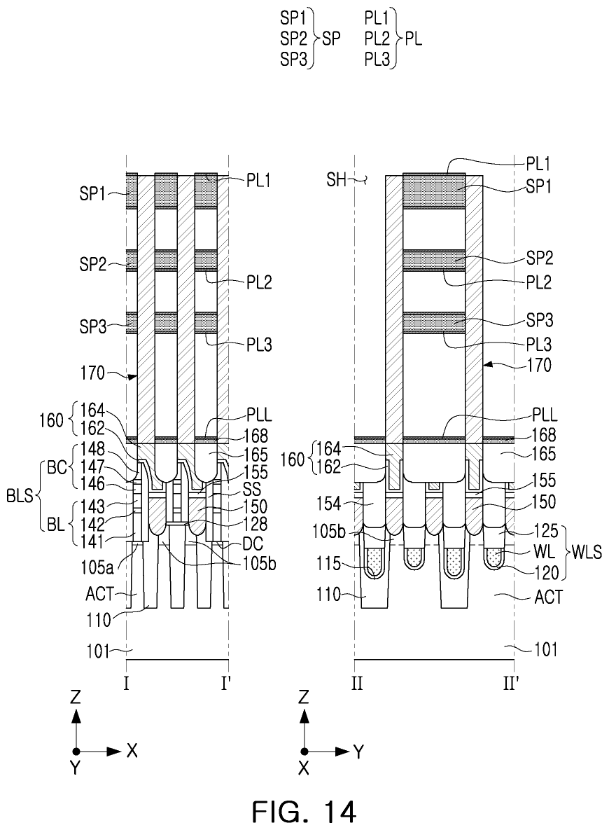

The gate insulating layer 250 may surround a sidewall of the channel layer 230 and may be interposed between the channel layer 230 and the gate electrode 240. For example, as illustrated in FIG. 14, the entire sidewall of the channel layer 230 may be surrounded by the gate insulating layer 250, and a portion of a sidewall of the gate electrode 240 may be in contact with the gate insulating layer 250. In other example embodiments, the gate insulating layer 250 may extend in a direction of extension of the gate electrode 240 (that is, the first direction (X-direction)), and only two sidewalls opposing the gate electrode 240, among sidewalls of the channel layer 230, may be in contact with the gate insulating layer 250. The term “surround” (or “surrounded,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

In example embodiments, the gate insulating layer 250 may be formed of a silicon oxide film, a silicon oxynitride film, a high-k dielectric film having a dielectric constant higher than that of the silicon oxide film, or combinations thereof. The high-K dielectric film may be formed of a metal oxide or a metal oxynitride. For example, the high-K dielectric film usable as the gate insulating layer 250 may be formed of HfO₂, HfSiO, HfSiON, HfTaO, HfTiO, HfZrO, ZrO₂, Al₂O₃, or combinations thereof, but the present inventive concept is not limited thereto.

A plurality of second insulating patterns 232 may extend on the plurality of first insulating patterns 222 in the second direction (Y-direction), and the channel layer 230 may be disposed between two adjacent second insulating patterns 232, among the plurality of second insulating patterns 232. In addition, between the two adjacent second insulating patterns 232, a first buried layer 234 and a second buried layer 236 may be disposed in a space between two adjacent channel layers 230. The first buried layer 234 may be disposed on a bottom portion of the space between the two adjacent channel layers 230, and the second buried layer 236 may be disposed on the first buried layer 234 to fill a remainder of the space between the two adjacent channel layers 230. An upper surface of the second buried layer 236 may be disposed at a level the same as that of an upper surface of the channel layer 230, and the second buried layer 236 may cover an upper surface of the gate electrode 240. Alternatively, the plurality of second insulating patterns 232 may be formed as a material layer continuous with the plurality of first insulating patterns 222, or the second buried layer 236 may be formed as a material layer continuous with the first buried layer 234.

A storage contact 260 may be disposed on the channel layer 230. The storage contact 260 may vertically overlap the channel layer 230, and may be arranged in a matrix form of being spaced apart from each other in the first direction (X-direction) and the second direction (Y-direction). The storage contact 260 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof, but the present inventive concept is not limited thereto. The upper insulating layer 262 may surround a sidewall of the storage contact 260 on the plurality of second insulating patterns 232 and the second buried layer 236.

An etch stop film 270 may be disposed on the upper insulating layer 262, and the information storage structure 280 may be disposed on the etch stop film 270. The information storage structure 280 may include a lower electrode 282, a dielectric layer 284, and an upper electrode 286.

The lower electrode 282 may pass through (i.e., extend in) the etch stop film 270 to be electrically connected to an upper surface of the storage contact 260. The lower electrode 282 may be formed as a pillar-type electrode extending in the third direction (Z-direction), but the present inventive concept is not limited thereto. In example embodiments, the lower electrode 282 may vertically overlap the storage contact 260, and may be arranged in a matrix form of being spaced apart from each other in the first direction (X-direction) and the second direction (Y-direction). Alternatively, a landing pad (not explicitly illustrated, but implied) may be further disposed between the storage contact 260 and the lower electrode 282, such that the lower electrode 282 may be arranged to have a hexagonal shape.

In the integrated circuit device 200, the information storage structure 280 may include a support layer SP (corresponding to SP in FIG. 2), a passivation layer PL (corresponding to PL in FIG. 2), a lower passivation layer PLL (corresponding to PLL in FIG. 2), and an interface layer 175 (corresponding to 175 in FIG. 2). The storage contact 260 may be referred to as a conductive region, and may be electrically connected to the lower electrode 282 of the information storage structure 280.

According to example embodiments of the present inventive concept, a passivation layer may be disposed on a support layer, thereby suppressing formation of an interface layer on the support layer. Accordingly, electrical bridging of lower electrodes may be reduced or prevented.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a lower structure having a conductive region; and
an information storage structure on the lower structure,
wherein the information storage structure includes:
a lower electrode electrically connected to the conductive region;
a support layer on a side surface of the lower electrode;
a dielectric layer on the lower electrode and the support layer;
an interface layer between the lower electrode and the dielectric layer;
passivation layers between the support layer and the dielectric layer; and
an upper electrode on the dielectric layer.

2. The semiconductor device of claim 1, wherein the passivation layers include a material different from that of the support layer.

3. The semiconductor device of claim 2, wherein the passivation layers include a halogen compound.

4. The semiconductor device of claim 1, wherein the interface layer includes niobium oxide and/or tantalum oxide.

5. The semiconductor device of claim 1, wherein at least one of the passivation layers is in contact with the side surface of the lower electrode.

6. The semiconductor device of claim 1, wherein the interface layer has a first portion on an upper surface of the lower electrode, the first portion extending in a horizontal direction parallel to an upper surface of the lower structure, and a second portion in contact with the support layer, the second portion extending in a vertical direction perpendicular to the upper surface of the lower structure.

7. The semiconductor device of claim 6, wherein a side surface of the first portion of the interface layer is in contact with at least one of the passivation layers.

8. The semiconductor device of claim 6, wherein an upper surface and/or a lower surface of the second portion of the interface layer is in contact with at least one of the passivation layers.

9. The semiconductor device of claim 1, further comprising:
an etch stop layer in contact with a lower region of the side surface of the lower electrode; and
a lower passivation layer between the etch stop layer and the dielectric layer.

10. The semiconductor device of claim 9, wherein an upper surface of the lower passivation layer is in contact with the interface layer.

11. The semiconductor device of claim 1, wherein a cross-sectional thickness of the passivation layers decreases as a distance from the lower electrode decreases.

12. The semiconductor device of claim 11, wherein a portion of the interface layer at least partially overlaps the passivation layer in a vertical direction perpendicular to an upper surface of the lower structure.

13. The semiconductor device of claim 11, wherein a cross-sectional thickness of the interface layer decreases as a distance from the support layer decreases.

14. The semiconductor device of claim 1, wherein a portion of the passivation layers is between the lower electrode and the interface layer.

15. The semiconductor device of claim 1, wherein a portion of the interface layer is between the passivation layers and the dielectric layer.

16. A semiconductor device, comprising:
a lower structure having conductive regions; and
an information storage structure on the lower structure,
wherein the information storage structure includes:
lower electrodes electrically connected to the conductive regions;
a support layer between the lower electrodes, the support layer having a support opening;
a dielectric layer on the lower electrodes and the support layer;
interface layers between the lower electrodes and the dielectric layer;
a passivation layer between the support layer and the dielectric layer; and
an upper electrode on the dielectric layer,
wherein in a plan view, the passivation layer extends along a side surface of the support layer exposed by the support opening, between the lower electrodes, and
the interface layers extend along side surfaces of the lower electrodes exposed by the support opening.

17. The semiconductor device of claim 16, wherein, in plan view, the passivation layer has an arc shape.

18. The semiconductor device of claim 16, wherein each of the side surfaces of the lower electrodes has a first portion in contact with the support layer, a second portion in contact with the passivation layer, and a third portion in contact with one of the interface layers.

19. The semiconductor device of claim 16, wherein, in a plan view, the interface layers are on a portion of the passivation layer and the passivation layer is spaced apart from the dielectric layer.

20. A semiconductor device, comprising:
a lower structure having a conductive region; and
an information storage structure on the lower structure,
wherein the information storage structure includes:
a lower electrode electrically connected to the conductive region;
a first support layer and a second support layer on a side surface of the lower electrode, the second support layer below the first support layer;
a dielectric layer on the lower electrode, the first support layer, and the second support layer;
an interface layer between the lower electrode and the dielectric layer;
a first passivation layer between the first support layer and the dielectric layer;
a second passivation layer between the second support layer and the dielectric layer; and
an upper electrode on the dielectric layer, and
wherein the interface layer has a first portion in contact with an upper surface of the lower electrode and the first passivation layer, and a second portion between the first support layer and the second support layer.
